(19) United States
(12) Patent Application Publication
(10) Pub. No.: US 2011/0067901 A1
(43) Pub. Date: Mar. 24, 2011

(54) PACKAGE SUBSTRATE

(76) Inventors: Jin Ho KIM, Gyunggi-do (KR); Seok Kyu LEE, Gyunggi-do (KR); Jae Joon LEE, Gyunggi-do (KR); Sung Won JEONG, Gyunggi-do (KR)

(21) Appl. No.: 12/614,411

(22) Filed: Nov. 7, 2009

(30) Foreign Application Priority Data
Sep. 23, 2009 (KR) 10-2009-0090098

(51) Int. Cl. H05K 1/00

(52) U.S. Cl. 174/250

(57) ABSTRACT

Disclosed is a package substrate, in which the plating area of a first plating layer formed on a layer which is to be connected to a motherboard is larger than the plating area of a second plating layer formed on a layer which is to be connected to an electronic part, and open portions are formed on the first plating layer, thus balancing the plating areas of the plating layers formed on the layers of the package substrate, thereby minimizing warpage of the package substrate due to differing coefficients of thermal expansion.

### CROSS REFERENCE TO RELATED APPLICATION

This application claims the benefit of Korean Patent Application No. 10-2009-0090098, filed Sep. 23, 2009, entitled “A package substrate”, which is hereby incorporated by reference in its entirety into this application.

### BACKGROUND OF THE INVENTION

1. Technical Field

The present invention relates to a package substrate.

2. Description of the Related Art

As an electronic apparatus is being manufactured to have increased performance and a smaller size, the number of terminals of an electronic part such as a semiconductor chip, a die and so on is remarkably increased. In order to easily mount such an electronic part on a motherboard, a package substrate which is adapted for the electrical connection between the electronic part and the motherboard is also made thinner.

Accordingly, a coreless structure which improves signal transmission properties and enables the thickness to be reduced by removing a core substrate is mainly employed in a package substrate.

FIG. 1 is a cross-sectional view showing a conventional package substrate having a coreless structure. The package substrate of FIG. 1 illustratively has a six-layer structure.

As shown in FIG. 1, the conventional package substrate has a multilayer coreless structure composed of an insulating layer 300 and negative and positive plating layers 100, 200 formed thereon. As such, a first layer to a third layer 1L, 2L, 3L constitute a lower layer Lb which will be mounted on a motherboard, and are configured such that a lower plating layer 100 is formed on the insulating layer 300. Also, a fourth layer to a sixth layer 4L, 5L, 6L constitute an upper layer Lu on which an electronic part will be mounted, and are configured such that an upper plating layer 200 is formed on the insulating layer 300. Further, in order to protect the outermost circuit layer from the external environment, a lower solder resist layer 400a is formed on the lower surface of the first layer 1L, an upper solder resist layer 400b is formed on the upper surface of the sixth layer 6L, and also, a bump 500 for mounting an electronic part is formed on the outermost upper plating layer 200c.

However, the conventional package substrate having a coreless structure has weaker strength compared to a structure using a core substrate, and thus it may easily warp. Such warpage occurs because layers of the package substrate use materials having different mechanical properties and have different coefficients of thermal expansion and thus exhibit different thermal behaviors for heat hysteresis in a reflow process.

In order to solve this problem, conventional attempts have been made to insert an additional reinforcing plate, to form an additional dummy pattern on a dummy region or to control the thickness or open area of a solder resist layer. Such attempts have been proven to be effective to some degree, but there is a need to perform the undesired actions of using an additional member or performing an additional process.

Table 1 below shows the plating area per layer of the package substrate of FIG. 1 and the plating area ratio. As is apparent from Table 1 below, the plating area of the lower layer Lb is larger than that of the upper layer Lu. In particular, the plating area of an electronic part mounting region is different by about 40% between the upper layer Lu and the lower layer Lb. Typically, the lower layer Lb of the package substrate performs as a ground function, and the upper layer Lu which is a region where the electronic part is mounted has a fine pattern structure, thus inevitably incurring the difference in plating area.

TABLE 1

| | | | Plating Area Ratio |
|---|---|---|---|
| | Plating | Plating | of Electronic Part |
| Layer | Area (%) | Area Ratio | Mounting Region |
| 1L | 70.75 | 76.57 | 53.7 |
| 2L | 79.20 | | 68.7 |
| 3L | 79.75 | | 71.0 |
| 4L | 83.10 | 81.95 | 83.9 |
| 5L | 82.90 | | 93.9 |
| 6L | 79.85 | | 93.3 |

Like this, in the case where the plating area of the lower plating layer 100 is different from that of the upper plating layer 200, the coefficients of thermal expansion between the upper layer Lu and the lower layer Lb cannot but be different from each other, undesirably being the major contributor to warping of the package substrate.

Conventionally, with the exclusion of plating layers 100, 200 mostly constituting the package substrate, attempts to insert an additional reinforcing plate or to adjust the thickness of a solder resist layer so as to prevent warpage of the package substrate have been made. But these attempts merely indirectly prevent warpage through reinforcing predetermined portions of the substrate.

Therefore, there are urgently required alternatives for preventing warpage of the package substrate inevitably resulting from the plating area deviations of the lower plating layer 100 and the upper plating layer 200.

### SUMMARY OF THE INVENTION

Accordingly, the present invention has been made keeping in mind the problems encountered in the related art and the present invention is intended to provide a package substrate in which the plating areas of plating layers formed on layers of the package substrate are balanced, so that warpage due to differences in the coefficient of thermal expansion of the plating layers is able to be minimized.

An aspect of the present invention provides a package substrate, wherein a first plating layer formed on a layer which is to be connected to a motherboard has a plating area larger than a plating area of a second plating layer formed on a layer which is to be connected to an electronic part, and open portions are formed on the first plating layer.

In this aspect, the open portions may be provided in a checked pattern.

In this aspect, the open portions may be provided as a plurality of open holes.

In this aspect, the open portions may be formed on the first plating layer so that the plating area of the first plating layer is equal to the plating area of the second plating layer.

In this aspect, the open portions may be formed on respective layers of the first plating layer so that the plating area per layer of the first plating layer on one side of a neutral plane of the package substrate is equal to the plating area per layer of the second plating layer which is symmetrically located on the other side of the neutral plane of the package substrate.

In this aspect, the open portions may be formed on the first plating layer formed on an outermost layer which is to be connected to the motherboard.

Another aspect of the present invention provides a package substrate, wherein a first plating layer formed on a layer, which is to be connected to a motherboard and is located on one side of a neutral plane of the package substrate, of a region corresponding to an electronic part mounting region of a layer, which is to be connected to an electronic part and is located on the other side of the neutral plane of the package substrate, has a plating area larger than a plating area of a second plating layer of the electronic part mounting region, and open portions are formed on the first plating layer.

In this aspect, the open portions may be provided in a checked pattern.

In this aspect, the open portions may be provided as a plurality of open holes.

In this aspect, the open portions may be formed on the first plating layer so that the plating area of the first plating layer is equal to the plating area of the second plating layer.

In this aspect, the open portions may be formed on respective layers of the first plating layer so that the plating area per layer of the first plating layer on the one side of the neutral plane of the package substrate is equal to the plating area per layer of the second plating layer which is symmetrically located on the other side of the neutral plane of the package substrate.

In this aspect, the open portions may be formed on the first plating layer formed on an outermost layer which is to be connected to the motherboard.

### BRIEF DESCRIPTION OF THE DRAWINGS

The features and advantages of the present invention will be more clearly understood from the following detailed description taken in conjunction with the accompanying drawings, in which:

FIG. 1 is a cross-sectional view showing a conventional package substrate having a coreless structure;

FIG. 2 is a schematic cross-sectional view showing a package substrate according to a first embodiment of the present invention;

FIGS. 3A and 3B are top plan views showing a plating layer formed on a layer, which will be connected to a motherboard, of the package substrate of FIG. 2; and

FIGS. 4A and 4B are top plan views showing a plating layer formed on a layer, which will be connected to a motherboard, of a package substrate according to a second embodiment of the present invention.

### DESCRIPTION OF SPECIFIC EMBODIMENTS

Hereinafter, embodiments of the present invention will be described in detail while referring to the accompanying drawings. Throughout the drawings, the same reference numerals refer to the same or similar elements. Also, redundant descriptions will be omitted. In the description, the terms “first”, “second” and so on are used only to distinguish one element from another element, to show the placing of certain amounts, a sequence or importance, and the elements are not defined by the above terms. Furthermore, descriptions of known techniques, even if they are pertinent to the present invention, are regarded as unnecessary and may be omitted in so far as they would make the characteristics of the invention unclear and muddy the description.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

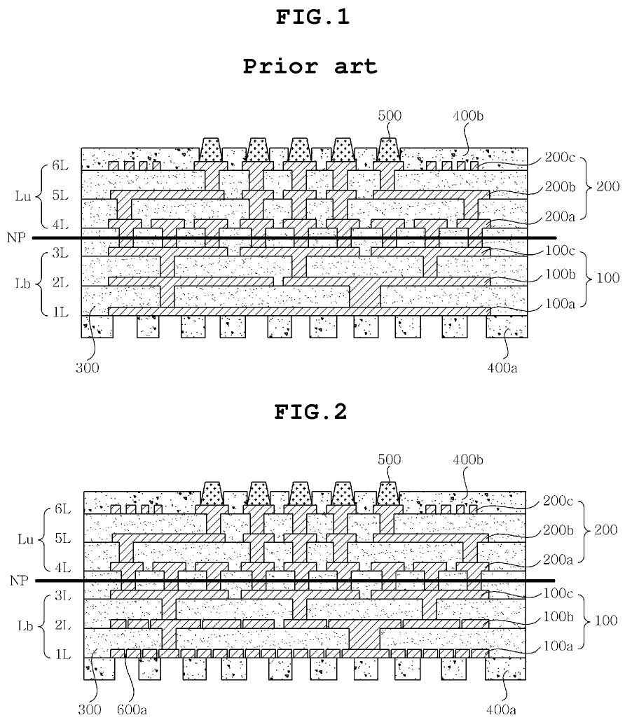

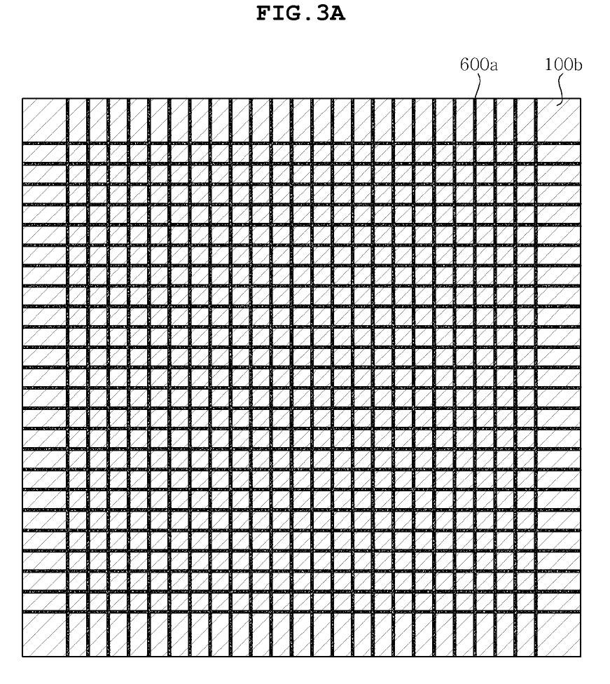

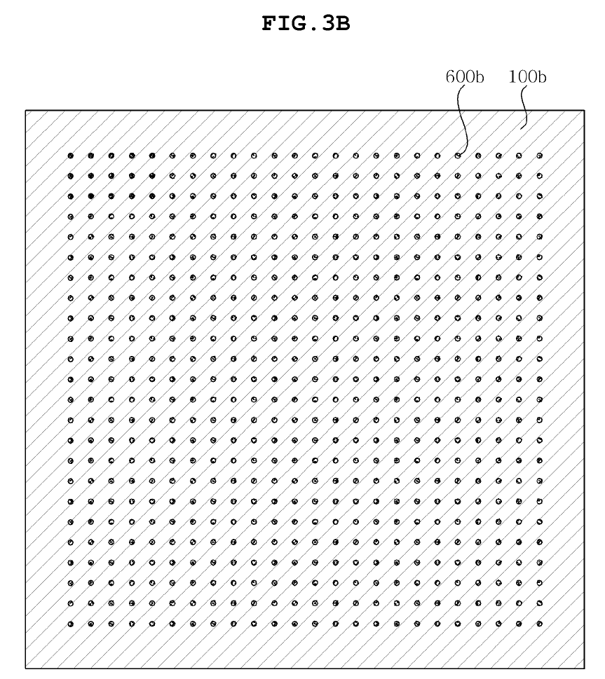

FIG. 2 is a schematic cross-sectional view showing a package substrate according to a first embodiment of the present invention, and FIGS. 3A and 3B are top plan views showing a plating layer formed on a layer, which will be connected to a motherboard, of the package substrate of FIG. 2. Below, the package substrate according to the present embodiment is described with reference to the above drawings.

As shown in FIGS. 2, 3A and 3B, the package substrate according to the present embodiment is configured such that the plating area of a first plating layer 100 of a layer Lb which will be connected to a motherboard is larger than the plating area of a second plating layer 200 of a layer Lu which will be connected to an electronic part, and open portions 600 are formed on the first plating layer 100.

Herein, the plating area indicates an area ratio, specifically, a two-dimensional area ratio, between the first plating layer 100 and the second plating layer 200 formed on the insulating layer 300.

Generally, in a package substrate, plating area deviations between a layer Lb which will be connected to a motherboard and a layer Lu which will be connected to an electronic part cannot be avoided. This is considered to be because the first plating layer 100 of the layer Lb which will be connected to a motherboard mainly performs a ground function and thus is provided in the form of a copper foil layer, whereas because the second plating layer 200 of the layer Lu which will be connected to an electronic part is patterned so as to be connected to an electrode terminal of the electronic part. The plating area deviations result in both sides of a neutral plane (NP) of the package substrate having different coefficients of thermal expansion, undesirably incurring warpage of the package substrate.

In the present invention, the first plating layer 100 has the open portions 600 formed thereon, whereby the plating area of the first plating layer 100 is made equal to the plating area of the second plating layer 200, thus minimizing the warpage of the package substrate. As such, because the open portions 600 may be formed in the course of patterning the first plating layer 100, mass manufacturing thereof is in practice considerably productive. Specifically, the open portions 600 are formed on a first plating layer 100a formed on a first layer 1L, a first plating layer 100b formed on a second layer 2L, and/or a first plating layer 100c formed on a third layer 3L.

As such, the open portions 600 may be formed to have a predetermined area on the first plating layer 100 so that the first plating layer 100 and the second plating layer 200 are imparted with reduced plating area deviations, that is, may have the plating areas equal to each other. The area of the open portions 600 may be appropriately controlled in consideration of the plating area deviations of the first plating layer 100 and the second plating layer 200.

For example, the open portions 600 may be provided in the form of a checked pattern (FIG. 3A) in which transverse lines and longitudinal lines intersect each other, or may be provided in the form of a plurality of open holes (FIG. 3B). The open portions 600 may be formed to have a uniform distribution on the first plating layer 100 in order to prevent the package substrate from warping due to position deviations thereof. For the sake of illustration, a state in which the open portions 600 are formed on the first plating layer 100b of the second layer 2L is shown. The forms of the open portions 600 of FIGS. 3A and 3B are merely illustrative, and may be variously changed, which also should be incorporated in the scope of the present invention.

Moreover, because the warpage of the package substrate is greatly affected by the plating layer formed at the outermost part of the layer thereof, the open portions 600 may be processed on the first plating layer 100a such that the plating area of the first plating layer 100a formed at the outermost part of the layer Lb is equal to the plating area of the second plating layer 200c formed at the outermost part of the layer Lu.

Furthermore, the open portions 600 may be formed on respective layers 1L, 2L, 3L of the first plating layer 100 so that the plating area per layer 1L, 2L, 3L of the first plating layer 100 on one side of the neutral plane (NP) of the package substrate is equal to the plating area per layer 4L, 5L, 6L of the second plating layer 200 which is symmetrically located on the other side of the neutral plane (NP) of the package substrate. Specifically, the open portions 600 are formed on the first plating layer 100a formed on the first layer 1L so that the plating area of the first plating layer 100a is equal to that of the second plating layer 200c formed on the sixth layer 6L. Also, the open portions 600 are formed on the first plating layer 100b formed on the second layer 2L so that the plating area of the first plating layer 100b is equal to that of the second plating layer 200b formed on the fifth layer 5L. Also, the open portions 600 are formed on the first plating layer 100c formed on the third layer 3L so that the plating area of the first plating layer 100c is equal to that of the second plating layer 200a formed on the fourth layer 4L.

In this way, the plating areas of the first plating layer 100 and the second plating layer 200 formed on the layers disposed symmetrically to each other are controlled, thereby reducing the plating area deviations of the layers. Thus, warpage which occurs due to plating area deviations of the layers even when the entire plating area is the same may be minimized.

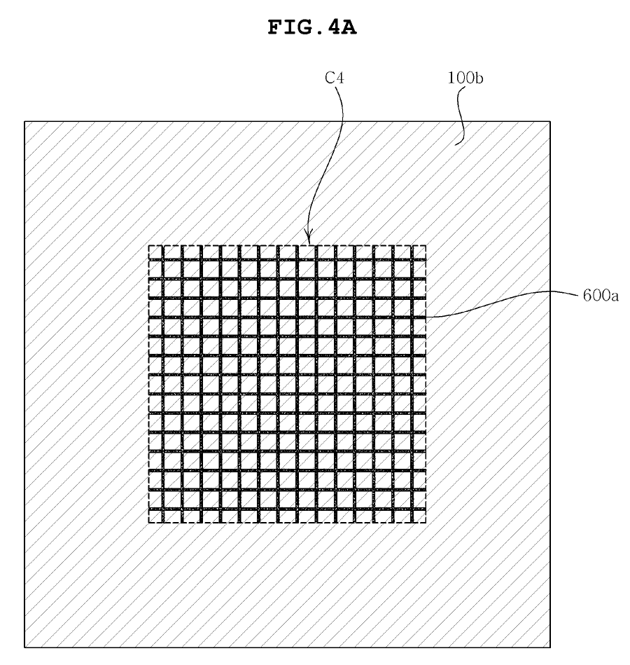

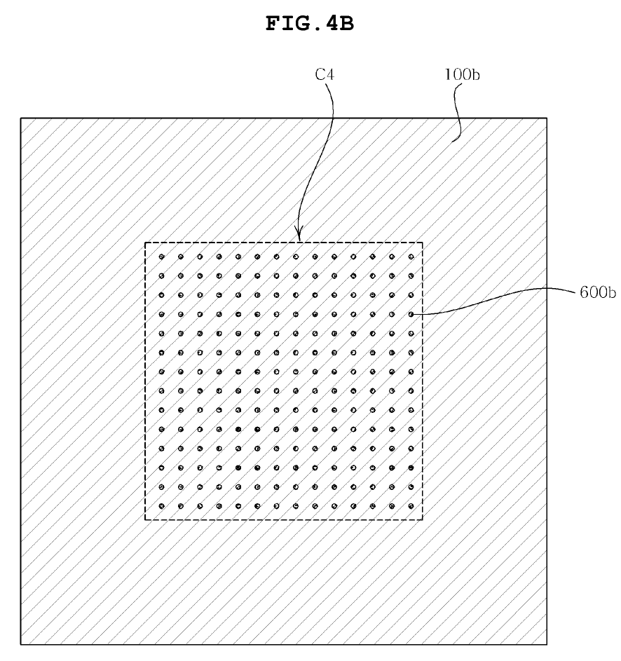

FIGS. 4A and 4B are top plan views showing a plating layer of a layer, which will be connected to a motherboard, of a package substrate according to a second embodiment of the present invention.

As shown in FIGS. 4A and 4B, the package substrate according to the present embodiment is configured such that the plating area of a first plating layer 100 formed on a layer, which will be connected to a motherboard and is located on one side of a neutral plane (NP) of the package substrate, of a region corresponding to an electronic part mounting region (C4) of a layer, which will be connected to an electronic part and is located on the other side of the neutral plane (NP) of the package substrate, is larger than the plating area of a second plating layer 200 of the electronic part mounting region (C4), and open portions 600 are formed on the first plating layer 100.

The present embodiment proposes a structure in which, in consideration of the excessive plating area deviations of the layer which will be connected to an electronic part and the layer which will be connected to a motherboard, based on the electronic part mounting region (C4), the plating deviation of the electronic part mounting region (C4) may be mitigated, thereby preventing the entire substrate from warping.

As is apparent from Table 1, the plating area ratio has a maximum plating area deviation of about 40% between the first plating layer 100 and the second plating layer 200 in the electronic part mounting region (C4). Hence, the open portions 600 are processed on the first plating layer 100 of a region corresponding to the electronic part mounting region (C4) except for the other regions, thereby drastically reducing plating area deviations, differences in coefficient of thermal expansion, and warpage of the package substrate.

As such, the open portions 600 may be provided in the form of a checked pattern (FIG. 4A) in which transverse lines and longitudinal lines intersect each other, or may be provided in the form of a plurality of open holes (FIG. 4B).

Also in the present embodiment, the plating areas of the outermost plating layers are made equal to each other. Furthermore, the plating areas of the plating layers of respective layers are made equal to each other.

As described hereinbefore, the present invention provides a package substrate. In the package substrate according to the present invention, a first plating layer which will be connected to a motherboard has open portions formed thereon so as to balance the plating area thereof with that of a second plating layer which will be connected to an electronic part. Thus, the differences in coefficient of thermal expansion resulting from plating area deviations of the plating layers formed on layers of the package substrate can be eliminated, thereby minimizing the warpage of the package substrate.

Also, in respective layers of the package substrate according to the present invention, the plating area of the first plating layer is controlled to be equal to the plating area of the second plating layer which is symmetrically located thereto, thereby reducing plating area deviations of the layers. Hence, the package substrate can be prevented from warping as a result of plating area deviations of the layers.

Also, according to the present invention, open portions are formed on the first plating layer of a region corresponding to an electronic part mounting region, thereby reducing the excessive plating area deviation of the electronic part mounting region, consequently minimizing the warpage of the package substrate.

Although the embodiments of the present invention regarding the package substrate have been disclosed for illustrative purposes, those skilled in the art will appreciate that a variety of different modifications, additions and substitutions are possible, without departing from the scope and spirit of the invention as disclosed in the accompanying claims. Accordingly, such modifications, additions and substitutions should also be understood as falling within the scope of the present invention.

What is claimed is:

1. A package substrate, wherein a first plating layer formed on a layer which is to be connected to a motherboard has a plating area larger than a plating area of a second plating layer formed on a layer which is to be connected to an electronic part, and open portions are formed on the first plating layer.

2. The package substrate as set forth in claim 1, wherein the open portions are provided in a checked pattern.

3. The package substrate as set forth in claim 1, wherein the open portions are provided as a plurality of open holes.

4. The package substrate as set forth in claim 1, wherein the open portions are formed on the first plating layer so that the plating area of the first plating layer is equal to the plating area of the second plating layer.

5. The package substrate as set forth in claim 1, wherein the open portions are formed on respective layers of the first plating layer so that the plating area per layer of the first plating layer on one side of a neutral plane of the package substrate is equal to the plating area per layer of the second plating layer which is symmetrically located on the other side of the neutral plane of the package substrate.

6. The package substrate as set forth in claim 1, wherein the open portions are formed on the first plating layer formed on an outermost layer which is to be connected to the motherboard.

7. A package substrate, wherein a first plating layer formed on a layer, which is to be connected to a motherboard and is located on one side of a neutral plane of the package substrate, of a region corresponding to an electronic part mounting region of a layer, which is to be connected to an electronic part and is located on the other side of the neutral plane of the package substrate, has a plating area larger than a plating area of a second plating layer of the electronic part mounting region, and open portions are formed on the first plating layer.

8. The package substrate as set forth in claim 7, wherein the open portions are provided in a checked pattern.

9. The package substrate as set forth in claim 7, wherein the open portions are provided as a plurality of open holes.

10. The package substrate as set forth in claim 7, wherein the open portions are formed on the first plating layer so that the plating area of the first plating layer is equal to the plating area of the second plating layer.

11. The package substrate as set forth in claim 7, wherein the open portions are formed on respective layers of the first plating layer so that the plating area per layer of the first plating layer on the one side of the neutral plane of the package substrate is equal to the plating area per layer of the second plating layer which is symmetrically located on the other side of the neutral plane of the package substrate.

12. The package substrate as set forth in claim 7, wherein the open portions are formed on the first plating layer formed on an outermost layer which is to be connected to the motherboard.
